(19) United States
(12) Patent Application Publication
(10) Pub. No.: US 2026/0075924 A1
(43) Pub. Date: Mar. 12, 2026

(54) WAFER BONDING METHOD AND SEMICONDUCTOR STRUCTURE OBTAINED BY THE SAME

(71) Applicant: TAIWAN SEMICONDUCTOR MANUFACTURING COMPANY, LTD., Hsinchu (TW)

(72) Inventors: Zheng-Yong LIANG, Hsinchu (TW); Yu-Yun PENG, Hsinchu (TW); Keng-Chu LIN, Hsinchu (TW); Wei-Ting YEH, Hsinchu (TW)

(73) Assignee: TAIWAN SEMICONDUCTOR MANUFACTURING COMPANY, LTD., Hsinchu (TW)

(21) Appl. No.: 18/827,029

(22) Filed: Sep. 6, 2024

(51) Int. Cl. H01L 21/822

(52) U.S. Cl. CPC H10D 84/038; H10D 88/01

(57) ABSTRACT

A method for manufacturing a semiconductor structure includes: forming a device structure on a device substrate, the device structure having a front surface, and including a buffer layer which is formed with the front surface; forming a first bonding layer on the front surface; forming a second bonding layer on a first carrier substrate; performing a bonding process such that the device structure and the first carrier substrate are bonded to each other through the first and second bonding layers; and before the bonding process, forming an anti-deformation layer which is located between the first bonding layer and the device structure, or between the second bonding layer and the first carrier substrate. A Young’s modulus of the anti-deformation layer is greater than a Young’s modulus of the buffer layer, and a compressive strength of the anti-deformation layer is greater than a compressive strength of the buffer layer.

### BACKGROUND

With dramatic advances in semiconductor technology, the dimension of semiconductor devices, such as metal oxide semiconductor field effect transistors (MOSFETs) is continuously scaled down, and the MOSFETs may be stacked vertically to form a three-dimensional integrated circuit (3DIC) with reduced power consumption and smaller footprint compared to conventional two-dimensional processes, so as to achieve improvement in performance. The concept of 3DIC applies not only to the local (transistor) level, but also to the intermediate (bond pad) level and the global (package) level. Wafer bonding or wafer stacking is a 3D packaging technology for stacking multiple wafers together, and is still undergoing vigorous development.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow diagram illustrating a method for manufacturing a semiconductor structure in accordance with some embodiments.

FIGS. 2 to 17 illustrate schematic views of intermediate stages of the method depicted in FIG. 1 in accordance with some embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “above,” “top,” “bottom,” “upper,” “lower,” “over,” “beneath,” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

For the purposes of this specification and appended claims, unless otherwise indicated, all numbers expressing amounts, sizes, dimensions, proportions, shapes, formulations, parameters, percentages, quantities, characteristics, or other numerical values used in the specification and claims, are to be understood as being modified in all instances by the terms “about” and “substantially” even if the terms “about” and “substantially” are not explicitly recited with the values, amounts or ranges. Accordingly, unless indicated to the contrary, the numerical parameters set forth in the following specification and appended claims are not and need not be exact, but may be approximations and/or larger or smaller than specified as desired, may encompass tolerances, conversion factors, rounding off, measurement error, and other factors known to those of skill in the art depending on the desired properties sought to be obtained by the presently disclosed subject matter. For example, the terms “about” and “substantially,” when used with a value, can capture variations of, in some aspects ± 10%, in some aspects ± 5%, in some aspects ± 2.5%, in some aspects ±1%, in some aspects ± 0.5%, and in some aspects ± 0.1% from the specified amount, as such variations are appropriate to perform the disclosed methods or employ the disclosed compositions.

The term “source/drain portion(s)” may refer to a source or a drain, individually or collectively dependent upon the context.

With the size miniaturization of transistors and metallization layers (e.g., metal lines, metal vias, through silicon vias, etc.), the alignment specification required for a bonding process (e.g., a die-to-die bonding, a die-to-wafer bonding, a wafer-to-wafer bonding, etc.) becomes more rigorous. In common practice, a compressive stress is inevitably applied during the bonding process, and structures formed on a substrate (or wafer) may have a certain degree of deformation due to the compressive stress. Therefore, the present disclosure is directed to a substrate bonding method (for example, but not limited to, a wafer-to-wafer bonding method) and a semiconductor structure obtained by the substrate bonding method. In an example of the substrate bonding method of the present disclosure, a carrier substrate is bonded to a device substrate which is formed with multiple semiconductor devices thereon, and an anti-deformation layer is used to prevent deformation of the semiconductor devices caused by the compressive stress, thereby improving an alignment performance between the semiconductor devices and conductive features which are connected to the semiconductor devices from a backside of the device substrate.

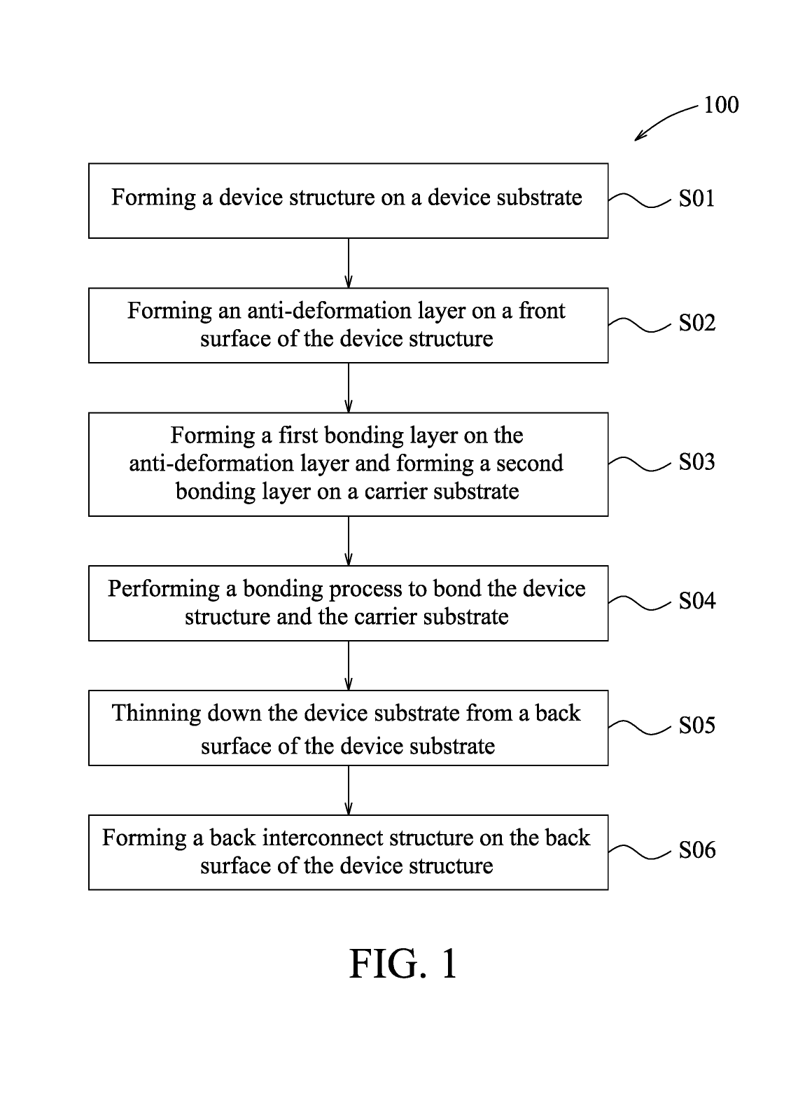

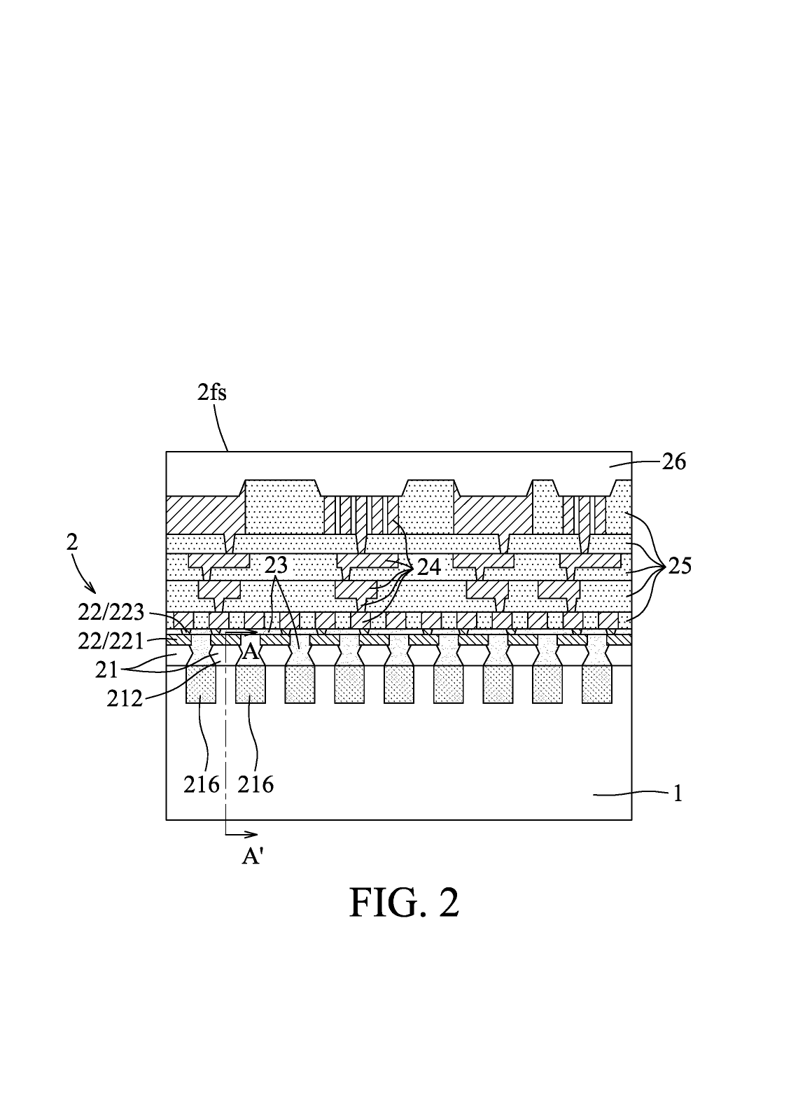

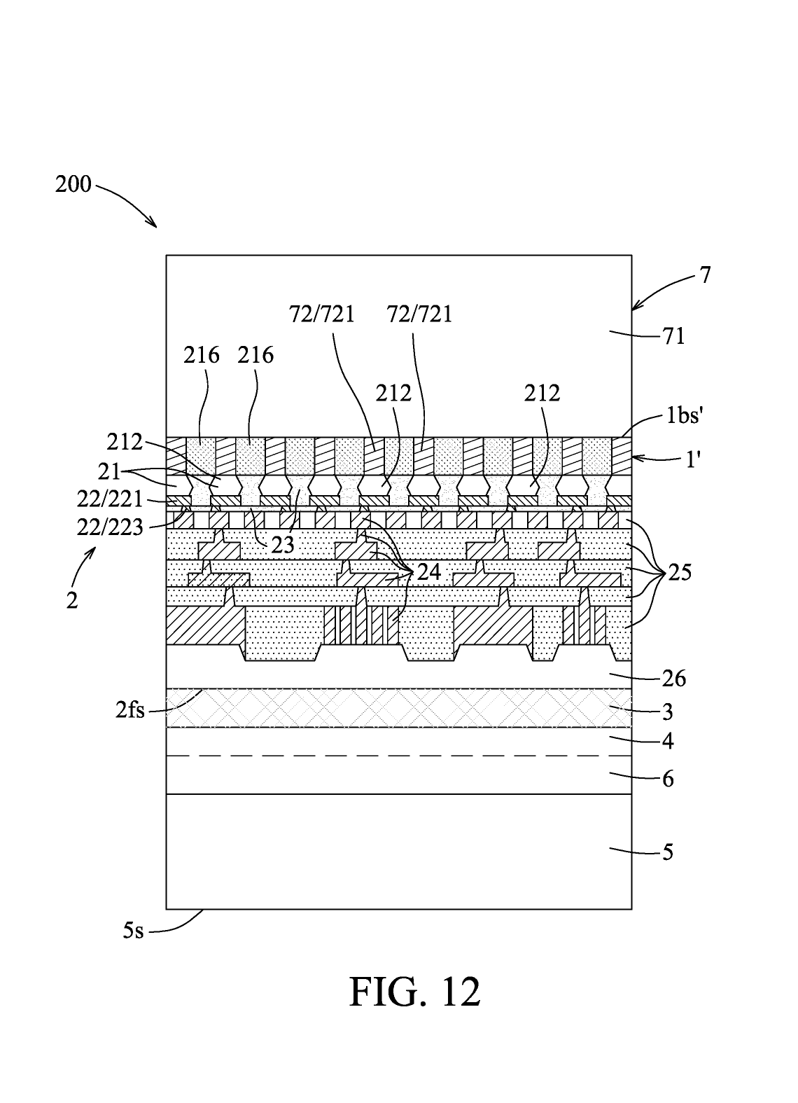

FIG. 1 is a flow diagram illustrating a method 100 for manufacturing a semiconductor structure (for example, but not limited to, a semiconductor structure 200 shown in FIGS. 12, 13 or 17) in accordance with some embodiments. The method 100 may include steps S01 to S06. FIGS. 2 to 17 illustrate schematic views of intermediate stages of the method 100 in accordance with some embodiments.

Referring to FIG. 1 and the example illustrated in FIG. 2, the method 100 begins at step S01, where a device structure 2 is formed on a device substrate 1.

In some embodiments, the device substrate 1 may have a predetermined thickness and a predetermined radius such that the device substrate 1 is suitable to be processed in subsequent steps. In some exemplary embodiments, the device substrate 1 may be a “12 inch” wafer having a radius of approximately 150 mm and with a thickness of approximately 765 µm to 775 µm. Other size and/or thickness suitable for the device substrate 1 are within the contemplated scope of the present disclosure.

In some embodiments, the device substrate 1 includes an elemental semiconductor material (such as silicon, diamond, or germanium in crystal, polycrystalline, or an amorphous form), a compound semiconductor material (such as silicon carbide, gallium arsenide, gallium phosphide, indium arsenide, or indium phosphide), an alloy semiconductor material (such as silicon germanium, silicon germanium carbide, gallium arsenide phosphide, gallium indium phosphide, gallium indium arsenide, gallium indium arsenic phosphide, aluminum indium arsenide, or aluminum gallium arsenide), or combinations thereof. In some embodiments, the device substrate 1 is a bulk semiconductor substrate, for example, but not limited to, a bulk substrate of silicon, germanium, silicon germanium, or other suitable semiconductor materials (such as the examples described earlier in the same paragraph). In some other embodiments not shown herein, the device substrate 1 is configured as a semiconductor-on-insulator substrate which includes a layer of a semiconductor material (such as the examples described earlier in the same paragraph) disposed on an insulator layer. In some embodiments, the device substrate 1 may be doped with n-type dopants (e.g., phosphorous, arsenic, or antimony) or p-type dopants (e.g., boron, aluminum, indium, or gallium) to serve as an n-type substrate or a p-type substrate, respectively. Other suitable materials and configurations for the device substrate 1 are within the contemplated scope of the present disclosure.

The device structure 2 has a front surface 2fs opposite to the device substrate 1, and includes a front-end-of-line (FEOL) portion formed on the device substrate 1, a middle-end-of-line (MEOL) portion formed on the FEOL portion opposite to the device substrate 1, a back-end-of-line (BEOL) portion formed on the MEOL portion opposite to the FEOL portion, and a buffer layer 26 formed on the BEOL portion opposite to the MEOL portion. The buffer layer 26 has the front surface 2fs of the device structure 2.

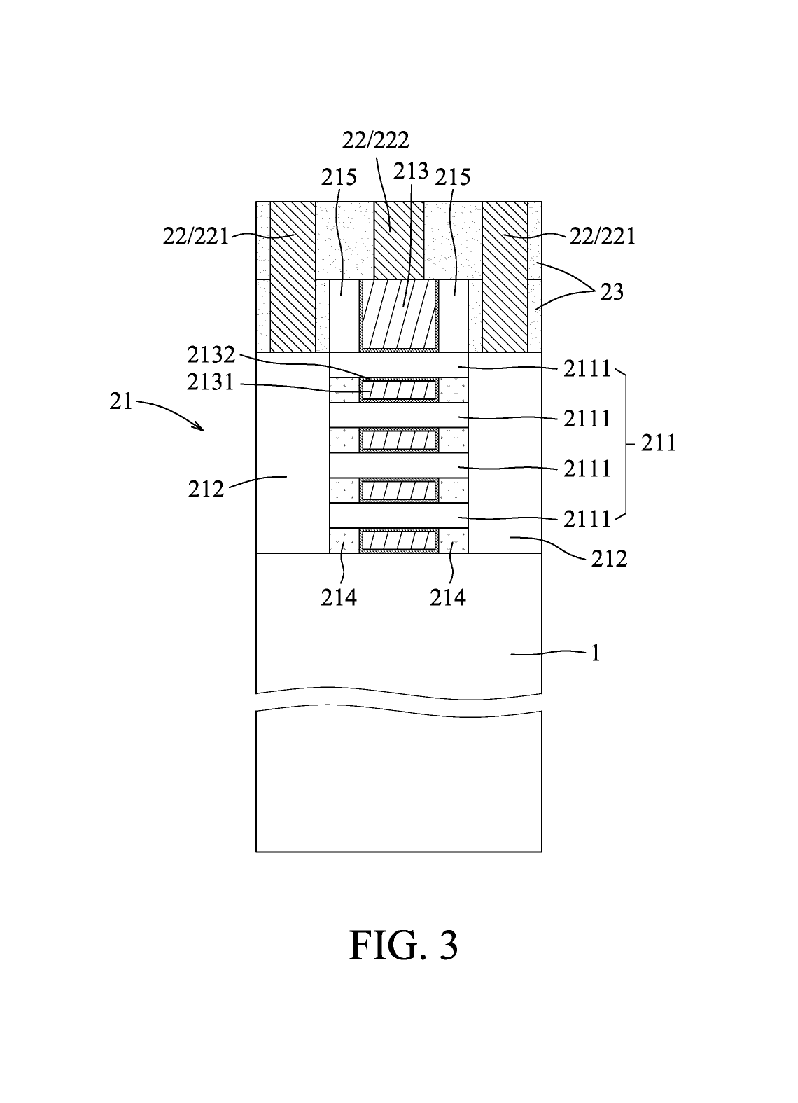

In some embodiments, the FEOL portion includes, for example, but not limited to, a logic circuitry with transistors (such as transistors 21 exemplarily shown in FIG. 2), a memory circuitry having memory elements, passive elements, and/or other suitable elements. FIG. 3 is a schematic enlarged sectional view taken along line A-A’ of FIG. 2 to illustrate the configuration of one of the transistors 21 in accordance with some embodiments. In some embodiments, the transistors 21 are each configured as a metal-oxide-semiconductor field-effect transistor (MOSFET) which includes a channel portion 211, two source/drain portions 212 (one of which is shown in FIG. 2) which are respectively disposed at two opposite sides of the channel 211, and a gate portion 213 which is disposed on the channel portion 211. The transistor 21 shown in FIG. 3 is configured as a gate-all-around (GAA) structure, in which the channel portion 211 includes channel layers 2111 and the gate portion 213 is disposed around the channel layers 2111. The gate portion 213 includes a gate electrode 2131 and a gate dielectric layer 2132 disposed to separate the gate electrode 2131 from the channel layers 2111. The transistor 21 further includes inner spacers 214 disposed to separate the gate portion 213 from the source/drain portions 212, and two gate spacers 215 formed at two opposite sides of the gate portion 213, respectively. In some embodiments, as shown in FIG. 2, the device substrate 1 may be formed with trench isolations 216 to separate two adjacent ones of the transistors 21. In some embodiments, the trench isolations 216 may each be a shallow trench isolation (STI), a deep trench isolation (DTI), or other suitable structures. In some embodiments, the trench isolations 216, the inner spacers 214 and the gate spacers 215 each may include silicon oxide, silicon nitride, silicon oxynitride, other suitable low-k dielectric materials, or combinations thereof.

In some other embodiments not shown herein, the transistors may include a fin-type field-effect transistor (FinFET), a complementary field-effect transistor (CFET) which includes a lower GAA transistor and an upper GAA transistor sequentially formed over the device substrate 1, a fork-sheet transistor which includes two GAA transistors spaced part from each other through a wall portion which is formed on a trench isolation, or other transistors having suitable three-dimensional configurations.

The MEOL portion includes, for example, but not limited to, metal contacts 22 and interlayer dielectric (ILD) layers 23 among the metal contacts 22, and/or other suitable elements. In some embodiments, the metal contacts 22 may include source/drain contacts 221 (two of which are shown in FIG. 3), gate contacts 222 (one of which is shown in FIG. 3), and via contacts 223. The gate portion 213 may be connected to the BEOL portion through the gate contact 222. Each of the source/drain portions 212 may be connected to the BEOL portion through the source/drain contact 221 and the via contact 223.

The BEOL portion includes, for example, but not limited to, metallization layers 24 (such as metal lines or metal vias) formed to be connected to the metal contacts 22, and inter-metal dielectric (IMD) layers 25 among the metallization layers 24. The device structure 2 may be formed using any appropriate materials and/or methods. In some embodiments, the MEOL portion and the BEOL portion may be together referred to as a front interconnect structure which is disposed between the transistors 21 in the FEOL portion and the buffer layer 26. The front interconnect structure includes a front dielectric portion which is formed to cover the transistors 21, and front conducive features which are formed in the front dielectric portion and which are connected to the transistors 21. The front dielectric portion includes the ILD layers 23 and the IMD layers 25. The front conductive features include the metal contacts 22 and the metallization layers 24.

In some embodiments, an upper surface of the BEOL portion opposite to the device substrate 1 may have a topography with a height variation of about 200 nm or less. Hence, the buffer layer 26 is formed on the upper surface of the BEOL portion to eliminate or alleviate such height variation. The buffer layer 26 is formed by atomic layer deposition (ALD), physical vapor deposition (PVD), chemical vapor deposition process (CVD), or other suitable deposition techniques, followed by a planarization process (e.g., chemical mechanical polishing), so that the front surface 2fs of the device structure 2 is a planar surface. In some embodiments, the buffer layer 26 is made of a buffer material which includes silicon oxide, nitrogen-doped silicon oxide, carbon-doped silicon oxide, silicon oxycarbon nitride, or combinations thereof. The buffer material is in an amorphous phase. Since amorphous silicon oxide has a relatively low thermal conductivity (e.g., about 1 W/mK), in certain embodiments, the buffer layer 26 may tend to have a reduced thickness so as to improve thermal dissipation of the device structure 2. In some embodiments, the buffer layer 26 may have a thickness not greater than about 300 nm. As the buffer layer 26 is thinned down for achieving an improved thermal dissipation, the thickness of the buffer layer 26 may be insufficient to absorb a compressive stress during a bonding process, thereby adversely impacting the transistors 21 in the FEOL portion. To be specific, in some embodiments, a Young’s modulus of amorphous silicon oxide ranges from about 40 GPa to about 80 GPa. In some embodiments, a compressive strength of amorphous silicon oxide ranges from about 100 MPa to about 500 MPa, or from about 300 MPa to about 500 MPa. In some embodiments, a Young’s modulus of copper (which is a conductive material widely used for forming the metallization layers 24) ranges from about 110 GPa to about 135 GPa. In some embodiments, a compressive strength of copper ranges from about 200 GPa to about 300 GPa. It is noted that the Young’s modulus and the compressive strength of amorphous silicon oxide are both smaller than those of copper. Thus, when a compressive stress is applied, a strain (or deformation) of the buffer layer 26 is greater than a strain (or deformation) of the metallization layers 24, and fractures in the buffer layer 26 may occur earlier than fractures in the metallization layers 24. Although the metallization layers 24 have a relatively high Young’s modulus, the metallization layers 24 have ductile characteristics, and may have a large deformation before fracture occurs. Therefore, an anti-deformation layer (to be described layer) is provided to prevent the transistors 21 in the FEOL portion from deformation which may be caused by the deformation of the buffer layer 26 and the metallization layers 24.

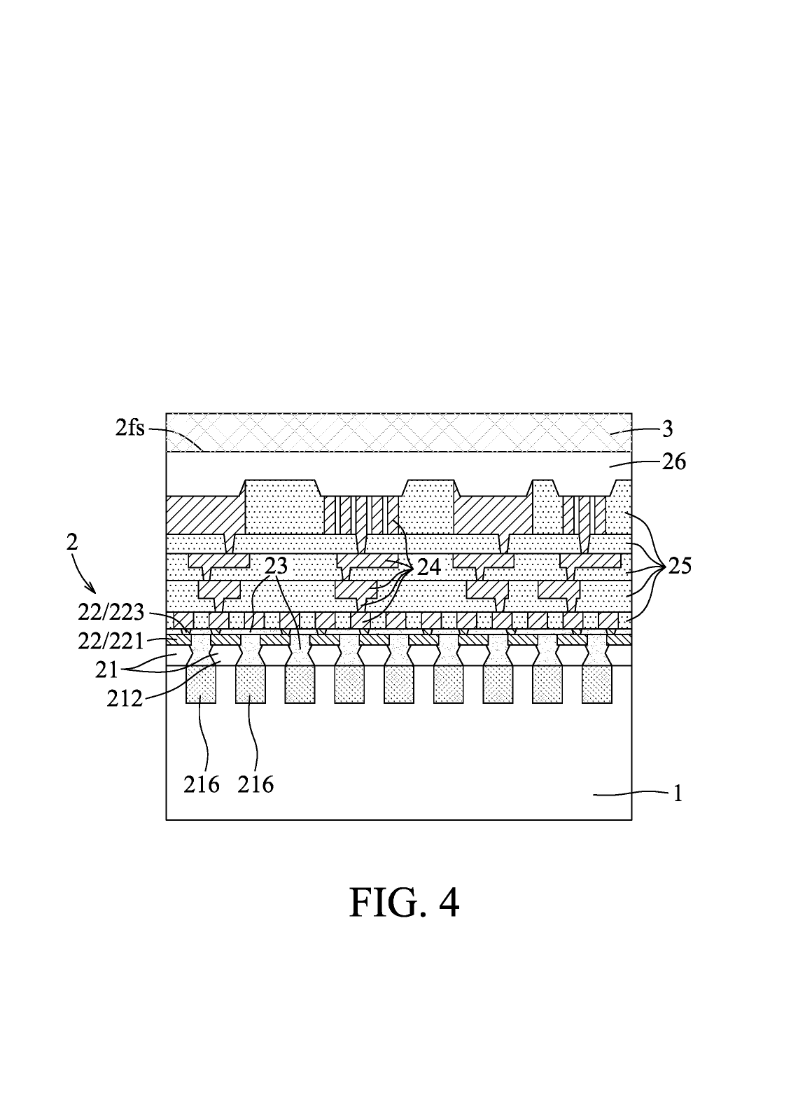

Referring to FIG. 1 and the example illustrated in FIG. 4, the method 100 proceeds to step S02, where an anti-deformation layer 3 is formed on the front surface 2fs of the device structure 2. FIG. 4 is a schematic sectional view similar to that shown in FIG. 2, but illustrating the structure after step S02.

The anti-deformation layer 3 is formed on the buffer layer 26 opposite to the BEOL portion. The anti-deformation layer 3 has a Young’s modulus that is greater than the Young’s modulus of the buffer layer 26, and has a compressive strength that is greater than the compressive strength of the buffer layer 26. In some embodiments, the Young’s modulus of the anti-deformation layer 3 may be even greater than the Young’s modulus of the metallization layers 24. Thus, when a compressive stress is applied, a strain (or deformation) of the anti-deformation layer 3 is relatively small, and the structures located beneath the anti-deformation layer 3 may be also less likely to be deformed. In some embodiments, the anti-deformation layer 3 includes or is made of silicon nitride, aluminum nitride, aluminum oxynitride, titanium nitride, tantalum nitride, aluminum oxide, titanium oxide, tantalum oxide, or combinations thereof. The materials suitable for forming the anti-deformation layer 3 as described above are in an amorphous phase. It is noted that the anti-deformation layer 3 is not a metal film which may have a film stress. The film stress is a characteristic of a film that is designed to cause strain in an underlying structure, and may be a tensile film stress or a compressive film stress. Since the anti-deformation layer 3 formed of the abovementioned materials has negligible film stress, the device structure 2 is less likely to be effected or deformed by the anti-deformation layer 3. Furthermore, it is noted that the materials suitable for forming the anti-deformation layer 3 as described above have a thermal conductivity that is greater than the thermal conductivity (e.g., about 1 W/mK) of amorphous silicon oxide, and thus the provision of the anti-deformation layer 3 may be beneficial to thermal dissipation of the device structure 2. In some embodiments, the anti-deformation layer 3 may be formed by physical vapor deposition (PVD), chemical vapor deposition (CVD), atomic layer deposition (ALD), or other suitable deposition techniques. In some embodiments, an adhesion strength between the anti-deformation layer 3 and the buffer layer 26 is greater than about 1.6 J/m² so as to prevent the anti-deformation layer 3 and the buffer layer 26 from delamination. In some embodiments, the anti-deformation layer 3 has a thermal stability greater than about 300°C. That is, metal elements or impurities (e.g., carbon, nitrogen, hydrogen, etc.) in the anti-deformation layer 3 are less likely to outgas or diffuse outward away from the anti-deformation layer 3 even at an elevated temperature (e.g., at a temperature ranging from about 300°C to about 600°C). The thermal stability of the anti-deformation layer 3 may be determined by, for example, thermogravimetric analysis, or gas chromatography–mass spectrometry (GC-MS). In some embodiments, the anti-deformation layer 3 has a thickness ranging from about 5 nm to about 300 nm (e.g., about 5 nm to about 100 nm, about 10 nm to about 100 nm, or about 10 nm to about 300 nm). When the anti-deformation layer 3 is too thin, such anti-deformation layer 32 may be, for example, but not limited to, formed as a plurality of islands rather than a continuous film and thus have insufficient mechanical strength. When the anti-deformation layer 3 is too thick, it may be not beneficial to thermal dissipation of the device structure 2 or may incur higher cost of semiconductor fabrication.

In some embodiments, the anti-deformation layer 3 is made of amorphous aluminum oxide. The amorphous aluminum oxide layer 3 has a Young’s modulus ranging from about 350 GPa to about 400 GPa, and has a compressive strength ranging from about 0.8 GPa to about 4 GPa. Furthermore, the amorphous aluminum oxide layer 3 has a thermal conductivity ranging from about 1.5 W/mK to about 5 W/mK, and has a coefficient of thermal expansion ranging from about 6E-6 K⁻¹ to about 8E-6 K⁻¹.

In some embodiments, the amorphous aluminum oxide layer 3 is formed by CVD at a temperature ranging from about 250°C to about 400°C. In such case, the amorphous aluminum oxide layer 3 has a thickness ranging from about 10 nm to about 300 nm or from about 10 nm to about 100 nm. A precursor gas used in CVD for forming the amorphous aluminum oxide layer 3 is provided to react with an oxygen-containing gas (e.g., water vapor, etc.), and may include aluminum alkoxides, aluminum halides, or combinations thereof.

In some other embodiments, the amorphous aluminum oxide layer 3 is formed by ALD at a temperature ranging from about 100°C to about 400°C. In such case, the amorphous aluminum oxide layer 3 has a thickness ranging from about 5 nm to about 300 nm or from about 5 nm to about 100 nm. A precursor gas used in ALD for forming the amorphous aluminum oxide layer 3 is provided to react with an oxygen-containing gas (e.g., water vapor, etc), and may include trimethylaluminum or other suitable precursor gases. In certain embodiments, the amorphous aluminum oxide layer 3 formed by CVD or ALD may have a roughness less than about 10 Å. In certain embodiments, the amorphous aluminum oxide layer 3 formed by CVD or ALD may be further planarized by a polishing process using a polishing agent such as colloidal silica, alumina, or ceria, so as to minimize the roughness thereof.

In some embodiments, the anti-deformation layer 3 is made of amorphous titanium oxide. The amorphous titanium oxide layer 3 has a Young’s modulus ranging from about 150 GPa to about 300 GPa, and has a compressive strength ranging from about 150 MPa to about 500 MPa. Furthermore, the amorphous titanium oxide layer 3 has a thermal conductivity ranging from about 2 W/mK to about 8.5 W/mK, and has a coefficient of thermal expansion ranging from about 6.14E-6 K⁻¹ to about 8.14E-6 K⁻¹.

In some embodiments, the amorphous titanium oxide layer 3 is formed by plasma-enhanced chemical vapor deposition (PECVD) at a temperature ranging from about 25°C to about 400°C. In such case, the amorphous titanium oxide layer 3 has a thickness ranging from about 10 nm to about 300 nm or from about 10 nm to about 100 nm. A precursor gas used in PECVD for forming the amorphous titanium oxide layer 3 is provided to react with an oxygen-containing gas (e.g., water vapor, oxygen gas, ozone gas, a gas mixture of oxygen and hydrogen gas, etc.), and may include titanium halides (such as titanium tetrachloride) or other suitable precursor gases.

In some other embodiments, the amorphous titanium oxide layer 3 is formed by plasma-enhanced atomic layer deposition (PEALD) at a temperature ranging from about 90°C to about 300°C. In such case, the amorphous titanium oxide layer 3 has a thickness ranging from about 5 nm to about 300 nm or from about 5 nm to about 100 nm. A precursor gas used in PEALD for forming the amorphous titanium oxide layer 3 is provided to react with an oxygen-containing gas (e.g., water vapor, oxygen gas, ozone gas, a gas mixture of oxygen and hydrogen gas, etc.), and may include titanium tetrachloride, tetrakis(dimethylamino)titanium, or a combination thereof. In certain embodiments, the amorphous aluminum oxide layer 3 formed by PECVD or PEALD may have a roughness less than about 10 Å. In certain embodiments, the amorphous titanium oxide layer 3 formed by PECVD or PEALD may be further planarized by a polishing process using a polishing agent such as colloidal silica, alumina, or ceria, so as to minimize the roughness thereof.

In some embodiments, the anti-deformation layer 3 is made of amorphous tantalum oxide. The amorphous tantalum oxide layer 3 has a Young’s modulus ranging from about 300 GPa to about 400 GPa, and has a compressive strength ranging from about 1.5 GPa to about 4 GPa. Furthermore, the amorphous tantalum oxide layer 3 has a thermal conductivity ranging from about 1.5 W/mK to about 5 W/mK, and has a coefficient of thermal expansion ranging from about 6E-6 K⁻¹ to about 8E-6 K⁻¹.

In some embodiments, the amorphous tantalum oxide layer 3 is formed by PEALD at a temperature ranging from about 90°C to about 300°C. In such case, the amorphous tantalum oxide layer 3 has a thickness ranging from about 5 nm to about 300 nm or from about 5 nm to about 100 nm. A precursor gas used in PEALD for forming the amorphous tantalum oxide layer 3 is provided to react with an oxygen-containing gas (e.g., water vapor, oxygen gas, ozone gas, a gas mixture of oxygen and hydrogen gas, etc.), and may include tantalum halides (such as tantalum pentachloride), tantalum alkoxides (such as tantalum pentaethoxide (Ta(OC₂H₅)₅), pentakis(dimethylamino)tantalum (Ta(NMe₂)₅), pentakis(methylethylamino)tantalum (Ta(NMeEt)₅), tetrakis(dimethylamino)(diethylamino)tantalum (Ta(NMe₂)₄(NEt₂)), or combinations thereof. In certain embodiments, the amorphous tantalum oxide layer 3 formed by PEALD may have a roughness less than about 10 Å. In certain embodiments, the amorphous tantalum oxide layer 3 formed by PEAVD may be further planarized by a polishing process using a polishing agent such as colloidal silica, alumina, or ceria, so as to minimize the roughness thereof.

In some embodiments, the anti-deformation layer 3 is made of amorphous titanium nitride. The amorphous titanium nitride layer 3 has a Young’s modulus ranging from about 250 GPa to about 590 GPa, and has a compressive strength ranging from about 0.8 GPa to about 4.5 GPa or from about 0.8 GPa to about 4 GPa. Furthermore, the amorphous titanium nitride layer 3 has a thermal conductivity ranging from about 10 W/mK to about 30 W/mK, and has a coefficient of thermal expansion ranging from about 9E-6 K⁻¹ to about 11E-6 K⁻¹.

In some embodiments, the amorphous titanium nitride layer 3 is formed by PECVD at a temperature ranging from about 200°C to about 400°C. In such case, the amorphous titanium nitride layer 3 has a thickness ranging from about 10 nm to about 300 nm or from about 10 nm to about 100 nm. A precursor gas used in PECVD for forming the amorphous titanium nitride layer 3 is provided to react with a nitrogen-containing gas (e.g., ammonia gas, nitrogen gas, etc.), and may include titanium halides (such as titanium tetrachloride), tetrakis(dimethylamino)titanium, or a combination thereof.

In some other embodiments, the amorphous titanium nitride layer 3 is formed by PEALD at a temperature ranging from about 200°C to about 400°C. In such case, the amorphous titanium nitride layer 3 has a thickness ranging from about 5 nm to about 300 nm or from about 5 nm to about 100 nm. A precursor gas used in PEALD for forming the amorphous titanium nitride layer 3 is provided to react with a nitrogen-containing gas (e.g., ammonia gas, etc.), and may include tetrakis(dimethylamino)titanium, or other suitable precursor gases. In certain embodiments, the amorphous aluminum nitride layer 3 formed by PECVE or PEALD may have a roughness less than about 10 Å. In certain embodiments, the amorphous titanium nitride layer 3 formed by PECVD or PEALD may be further planarized by a polishing process using a polishing agent such as colloidal silica or alumina, so as to minimize the roughness thereof.

In some embodiments, the anti-deformation layer 3 is made of amorphous silicon nitride. The amorphous silicon nitride layer 3 has a Young’s modulus ranging from about 200 GPa to about 450 GPa, and has a compressive strength ranging from about 2 GPa to about 4 GPa. Furthermore, the amorphous silicon nitride layer 3 has a thermal conductivity ranging from about 1.5 W/mK to about 3 W/mK, and has a coefficient of thermal expansion ranging from about 3E-6 K⁻¹ to about 3.5E-6 K⁻¹.

In some embodiments, the amorphous silicon nitride layer 3 is formed by PECVD at a temperature ranging from about 25°C to about 400°C. In such case, the amorphous silicon nitride layer 3 has a thickness ranging from about 10 nm to about 300 nm or from about 10 nm to about 100 nm. A precursor gas used in PECVD for forming the amorphous silicon nitride layer 3 is provided to react with a nitrogen-containing gas (e.g., ammonia gas, nitrogen gas, etc.), and may include silicon halides (such as silicon tetrachloride), silane, or a combination thereof.

In some other embodiments, the amorphous silicon nitride layer 3 is formed by PEALD at a temperature ranging from about 250°C to about 400°C. In such case, the amorphous silicon nitride layer 3 has a thickness ranging from about 5 nm to about 300 nm or from about 5 nm to about 100 nm. A precursor gas used in PEALD for forming the amorphous silicon nitride layer 3 is provided to react with a nitrogen-containing gas (e.g., ammonia gas, etc.), and may include silicon halides (such as silicon tetrachloride), or other suitable precursor gases. In certain embodiments, the amorphous silicon nitride layer 3 formed by PECVD or PEALD may have a roughness less than about 10 Å. In certain embodiments, the amorphous silicon nitride layer 3 formed by PECVD or PEALD may be further planarized by a polishing process using a polishing agent such as colloidal silica, alumina, or ceria, so as to minimize the roughness thereof.

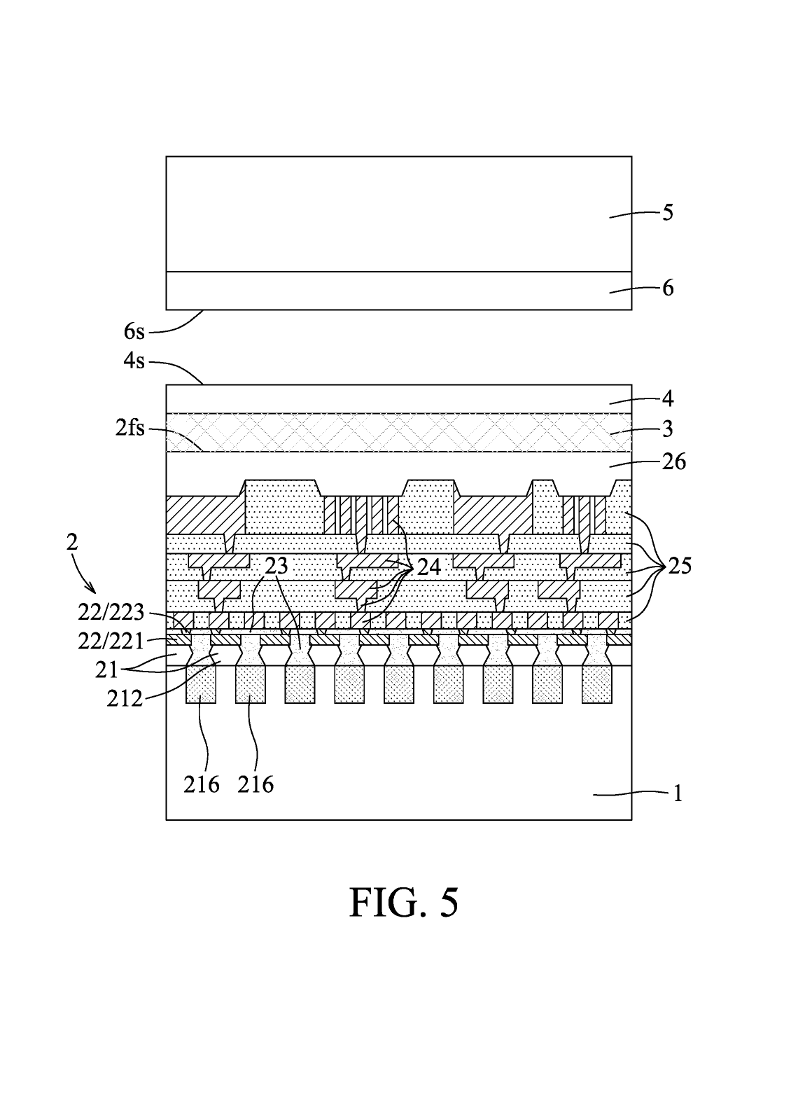

Referring to FIG. 1 and the example illustrated in FIG. 5, the method 100 proceeds to step S03, where a first bonding layer 4 is formed on the anti-deformation layer 3 opposite to the buffer layer 26, and a second bonding layer 6 is formed on a first carrier substrate 5. FIG. 5 is a schematic sectional view similar to that shown in FIG. 4, but illustrating the structure after step S03.

In some embodiments, the first carrier substrate 5 is a blanket substrate. The first carrier substrate 5 may include a semiconductor material such as the examples of the semiconductor material for forming the device substrate 1. In certain embodiments, the first carrier substrate 5 may be, for example, but not limited to, a blanket silicon substrate. The first carrier substrate 5 may have a predetermined thickness according to practical needs.

In some embodiments, the first bonding layer 4 is made of a first bonding material that is the same with a second bonding material of the second bonding layer 6. In some embodiments, each of the first bonding material and the second bonding material is made of amorphous silicon oxide. In some embodiments, the first bonding layer 4 and the second bonding layer 6 may have a total thickness ranging from about 100 nm to about 250 nm, but other range of values less than 100 nm (but not equal to 0 nm) are also within the contemplated scope of this disclosure. When the total thickness of the first bonding layer 4 and the second bonding layer 6 is too thick, it may be not beneficial to thermal dissipation of the device structure 2. In some embodiments, the first bonding layer 4 and the second bonding layer 6 may be respectively formed on the anti-deformation layer 3 and the first carrier substrate 5 by CVD, PVD, ALD, or other suitable deposition techniques.

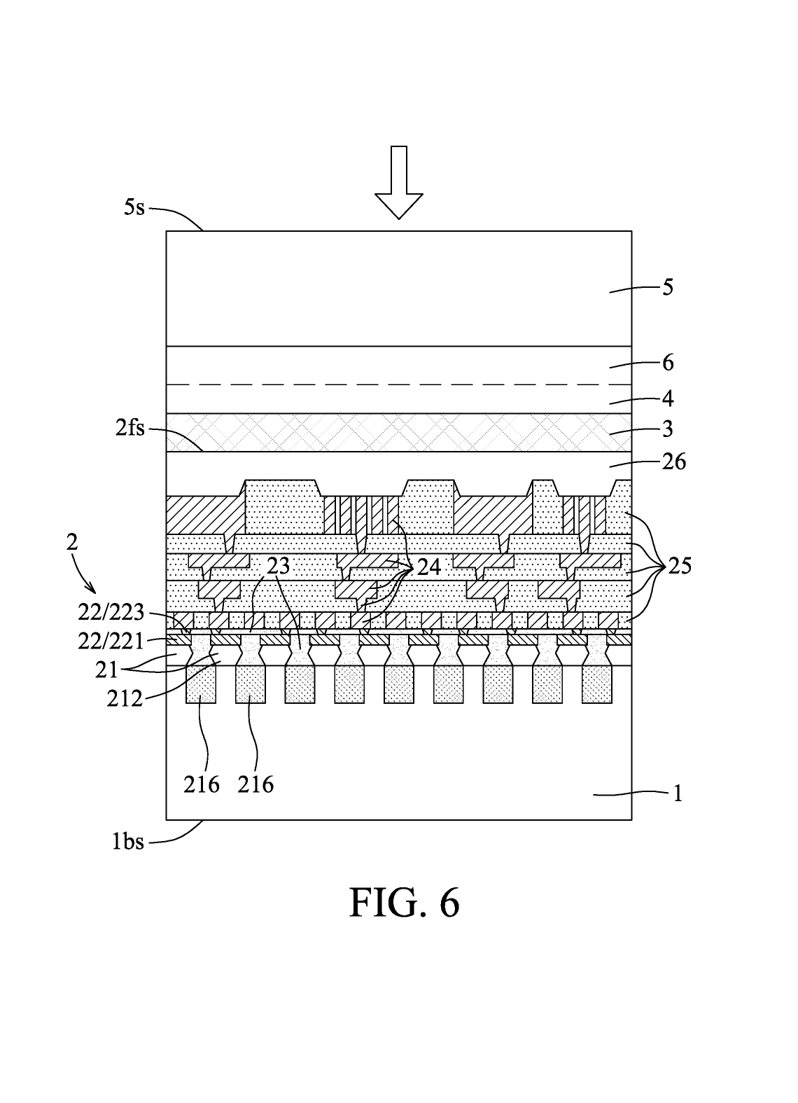

Referring to FIG. 1 and the example illustrated in FIG. 6, the method 100 proceeds to step S04, where a first bonding process is performed. FIG. 6 is a schematic sectional view similar to that shown in FIG. 5, but illustrating the structure after step S04.

In some embodiments, as shown in FIG. 6, the first carrier substrate 5 is bonded to the device structure 2 (which is formed with the anti-deformation layer 3) through the first and second bonding layers 4, 6. In some embodiments, the first and second bonding layers 4, 6 may be together referred to as a first bonding unit. In some embodiments, the first bonding process may include multiple sub-steps as described in the following.

First, the first bonding layer 4 and the second bonding layer 6 are each subjected to a plasma treatment to break Si—O—Si bonds on surface regions 4s, 6s (see FIG. 5) of the first and second bonding layers 4, 6 into Si—O bonds. In some embodiments, argon plasma is used in the plasma treatment. Afterwards, the first and second bonding layers 4, 6 are rinsed with water to form a water film over each of the surface regions 4s, 6s of the first and second bonding layers 4, 6, thereby forming Si—OH bonds thereon. Next, the first carrier substrate 5 and the device structure 2 (which is formed with the anti-deformation layer 3) thereon are aligned and brought toward each other, and then a compressive stress is applied onto a center of an upper surface 5s of the first carrier substrate 5 opposite to the device substrate 1, such that the first and second bonding layers 4, 6 are brought into contact with each other. In some embodiments, the compressive stress ranges from about 0.7 N to about 1.2 N, but other range of values are also within the contemplated scope of this disclosure. Thereafter, the first and second bonding layers 4, 6 are treated by a thermal treatment such that the Si—OH bonds are dehydrated to form Si—O—Si bonds, so that the first and second bonding layers 4, 6 are bonded together. In some embodiments, the thermal treatment is performed at a temperature ranging from about 260°C to about 600°C, but other range of values are also within the contemplated scope of this disclosure. Other suitable processes or steps for bonding the first carrier substrate 5 and the device structure 2 together are within the contemplated scope of the present disclosure.

In some alternative embodiments, formation of the anti-deformation layer 3 and the first and second bonding layers 4, 6 may not be performed in the sequence as described above in steps S02 and S03. To be specific, the anti-deformation layer 3 may be formed between the first carrier substrate 5 and the second bonding layer 6.

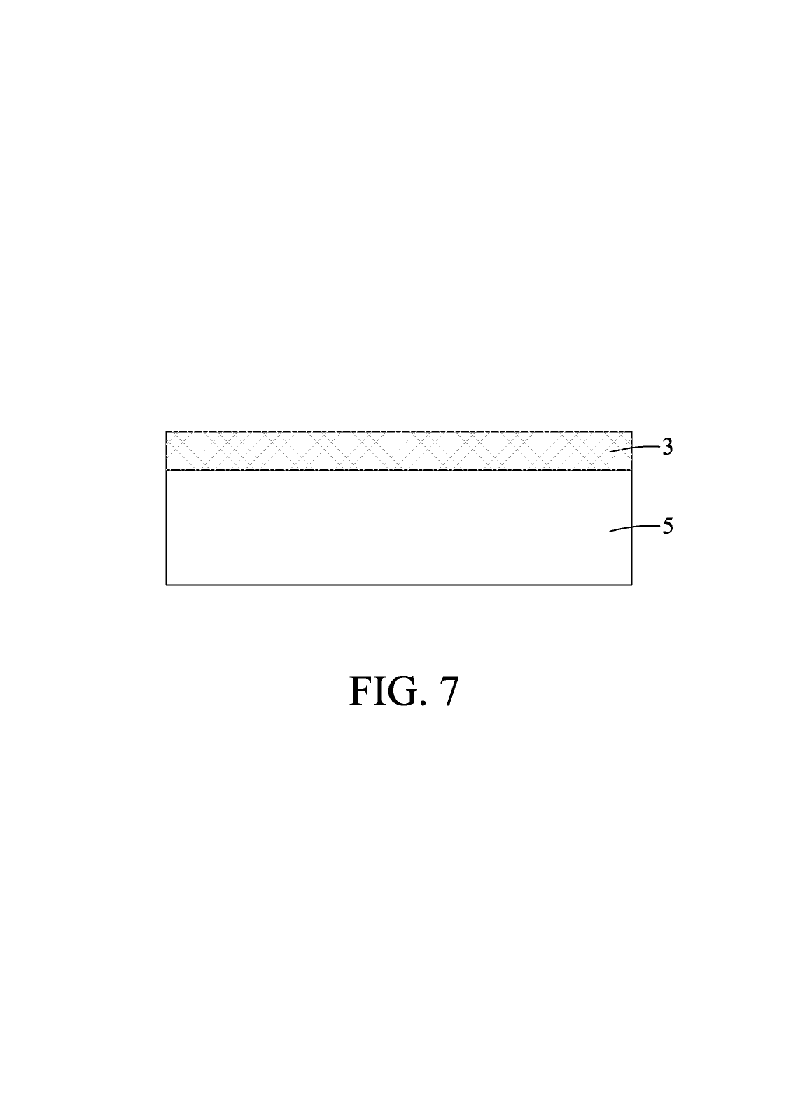

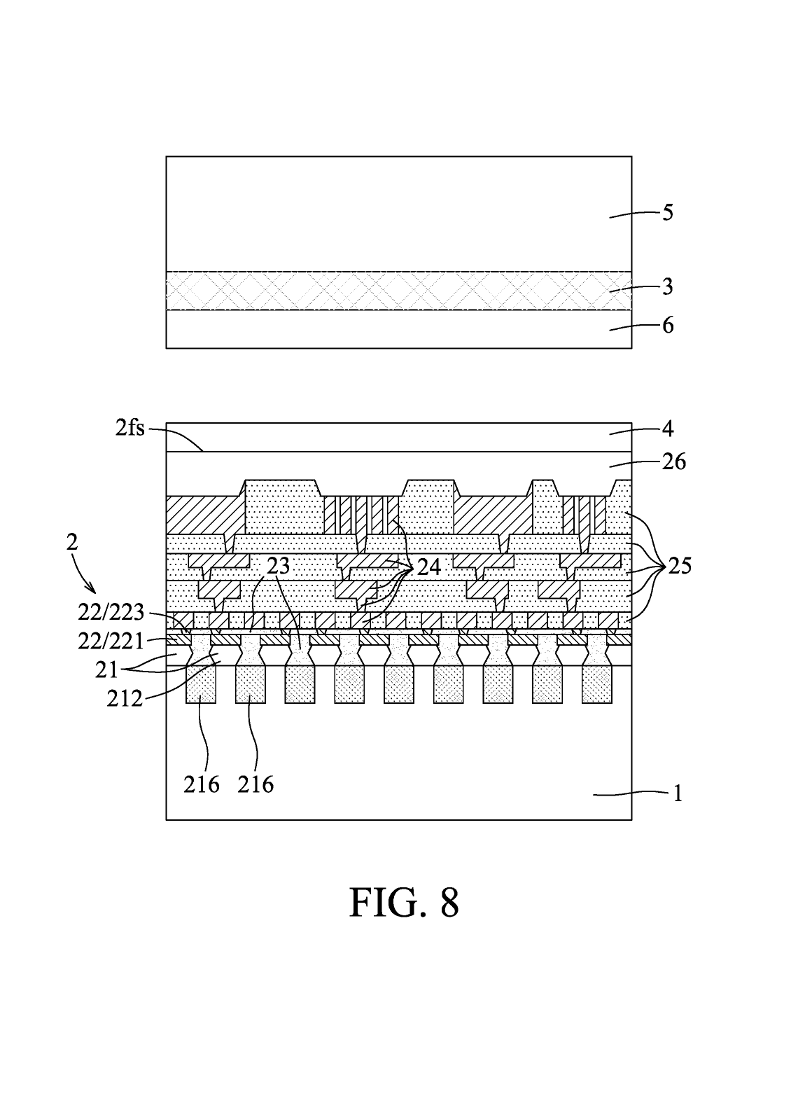

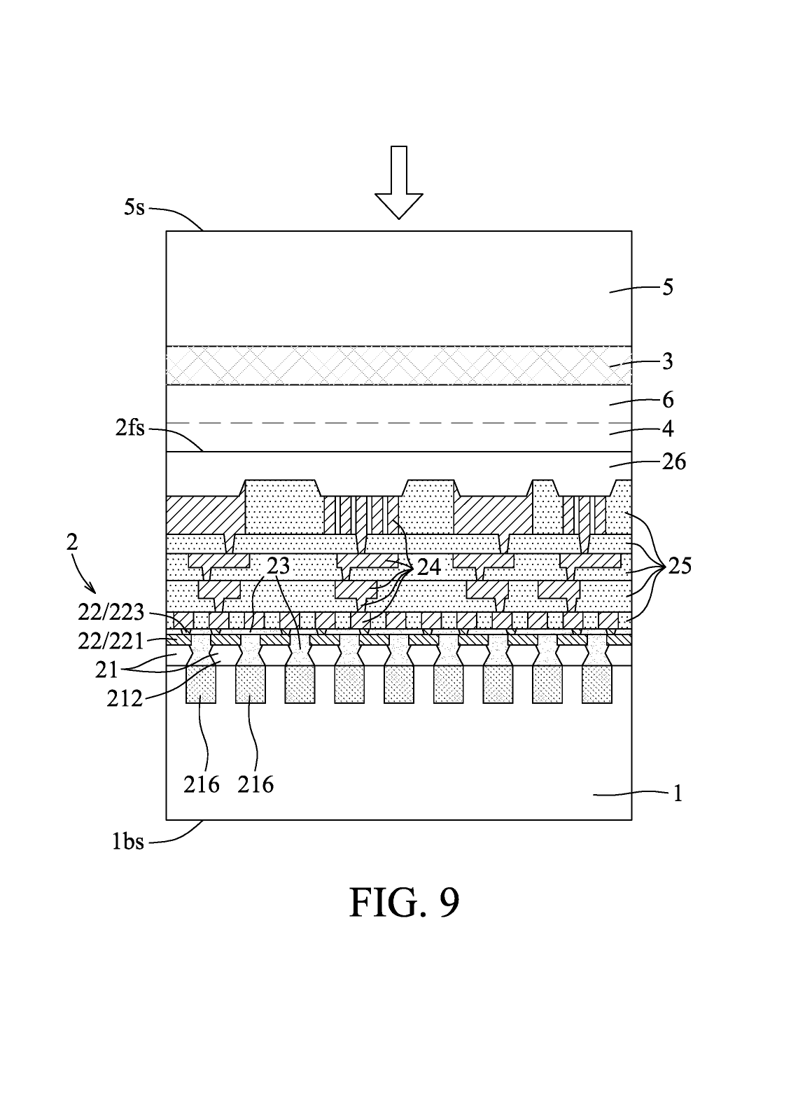

In detail, firstly, as shown in FIG. 7, the anti-deformation layer 3 is formed on the first carrier substrate 5. Afterwards, as shown in FIG. 8, the first bonding layer 4 is formed on the front surface 2fs of the device structure 2 opposite to the device substrate 1, and the second bonding layer 6 is formed on the anti-deformation layer 3 opposite to the first carrier substrate 5. Next, as shown in FIG. 9, the first bonding process is performed, such that the device structure 2 is bonded to the first carrier substrate 5 (which is formed with the anti-deformation layer 3) through the first and second bonding layers 4, 6. Since the material and process details of the anti-deformation layer 3, the first carrier substrate 5, the first and second bonding layers 4, 6 are similar to those as described above with reference to FIGS. 4 to 6, the details thereof are omitted for the sake of brevity.

It is worth noting that during application of the compressive stress on the upper surface 5s of the first carrier substrate 5 in the first bonding process, since the anti-deformation layer 3 is located between the first carrier substrate 5 and the device structure 2, and has a relatively high Young’s modulus, the deformation layer 3 is less likely to be deformed during the first bonding process. Furthermore, the anti-deformation layer 3 has a relatively high compressive strength, and thus is less likely to fracture during the first bonding process. Therefore, the device structure 2 (especially the transistors 21 which have an extremely small dimension) may be well protected by the anti-deformation layer 3, and may be less likely to deform or be offset from original position. As such, misalignment between the transistors 21 and conductive features which are to be formed in the next step to be connected to the transistors 21 can be alleviated or eliminated.

For purposes of simplicity and clarity, in the following steps, the structures subsequent to FIG. 6 will be illustrated, while the structures subsequent to FIG. 9 will not be illustrated.

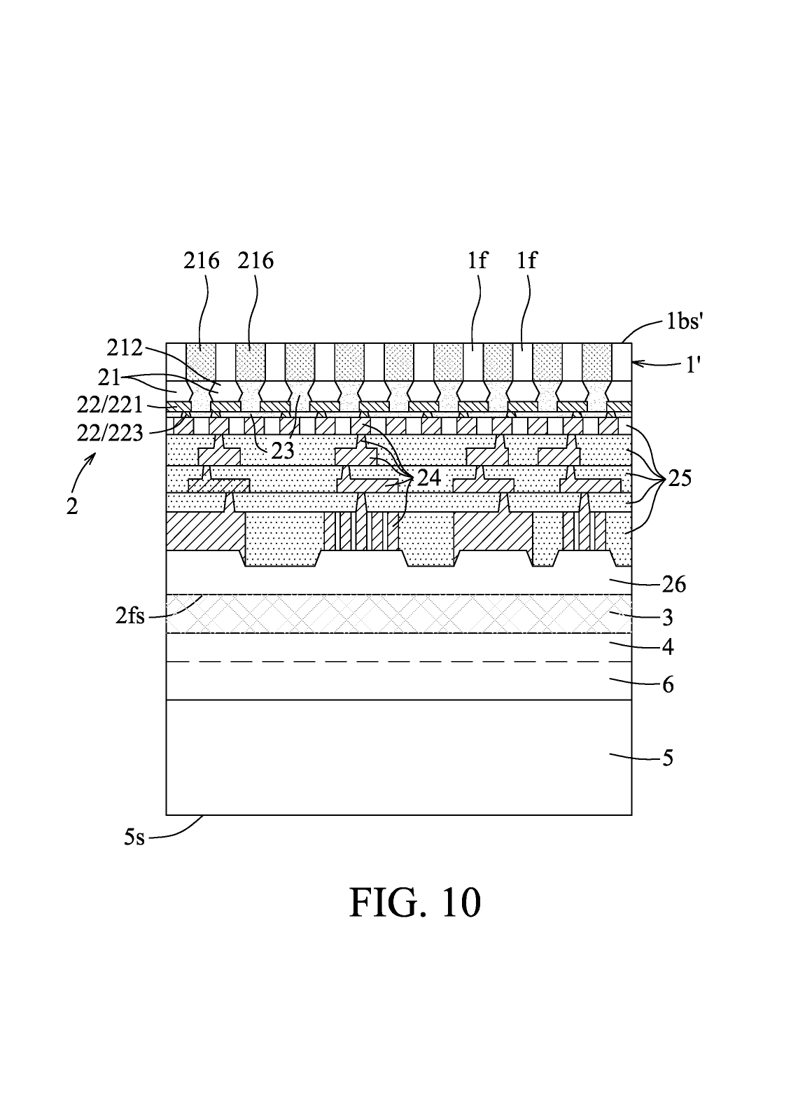

Referring to FIG. 1 and the example illustrated in FIG. 10, the method 100 proceeds to step S05, where the structure shown in FIG. 6 is flipped to place a back surface 1bs of the device substrate 1 (which is opposite to the front surface 2fs of the device structure 2) facing upward, and the device substrate 1 is thinned down from the back surface 1bs of the device substrate 1. FIG. 10 is a schematic sectional view similar to that shown in FIG. 6, but illustrating the structure after step S05.

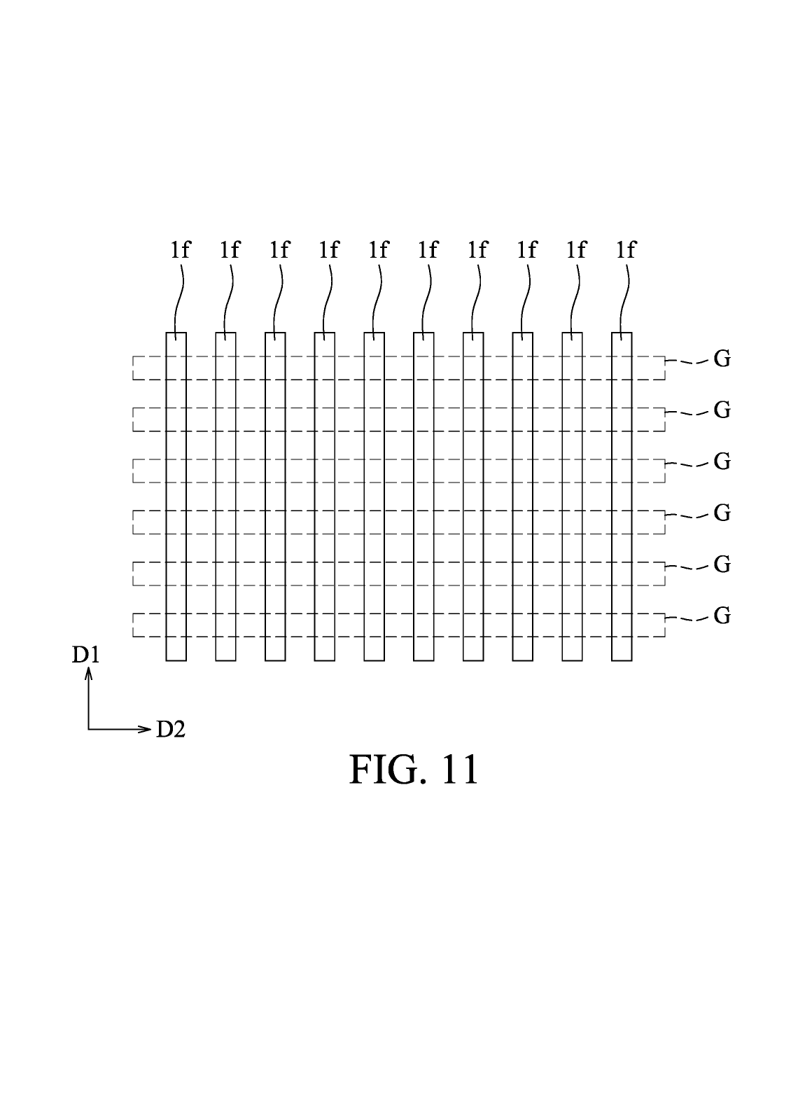

In some embodiments, the device substrate 1 is thinned down by a planarization process and/or an etching process until the trench isolations 216 are exposed. The device substrate that is being thinned down is denoted by the numeral 1’ and has a back surface 1bs’. FIG. 11 is a schematic backside view of the structure shown in FIG. 10 when viewed from the back surface 1bs’ in accordance with some embodiments, in which only fin portions 1f and gate structures (G) are shown. The fin portions 1f, which are formed in the device substrate 1’, are each elongated in a first direction (D1) and are disposed to alternate with the trench isolations 216 (see FIG. 10) in a second direction (D2) that is transverse to (e.g., perpendicular to) the first direction (D1). In addition, the gate structures (G) are each elongated in the second direction (D2) and are spaced apart from each other in the first direction (D1). The gate portion 213 of each of the transistors 21 shown in FIG. 3 is a portion of a corresponding one of the gate structures (G). In some embodiments, based on the layout design, some of the gate structures (G) may be each cut into several parts (not shown) which are spaced apart from each other in the second direction (D2).

In some embodiments, after step S05, a patterned photoresist layer (not shown) is formed on the back surface 1bs’ for alignment analysis. The patterned photoresist layer has first elongated patterns which are in positions corresponding to at least some of the fin portions 1f, and second elongated patterns which are in positions corresponding to at least some of the gate structures (G). That is, the first elongated patterns are each elongated in the first direction (D1) and are spaced apart from each other in the second direction (D2), and the second elongated patterns are each elongated in the second direction (D2) and are spaced apart from each other in the first direction (D1). Afterwards, an overlay measurement is conducted to evaluate the degree of an offset of the first elongated patterns from the corresponding fin portions 1f, and to evaluate the degree of an offset of the second elongated patterns from the corresponding gate structures (G). In some embodiments, with the provision of the anti-deformation layer 3, the offset of the first elongated patterns from the corresponding fin portions 1f, and the offset of the second elongated patterns from the corresponding gate structures (G) may be controlled to be less than about 5 nm. The patterned photoresist layer is removed after the overlay measurement.

Referring to FIG. 1 and the example illustrated in FIG. 12, the method 100 proceeds to step S06, where a back interconnect structure 7 is formed on the back surface 1bs’ of the device substrate 1’, thereby obtaining the semiconductor structure 200. FIG. 12 is a schematic sectional view similar to that shown in FIG. 10, but illustrating the structure after step S06.

The back interconnect structure 7 includes a back dielectric portion 71 and back conductive features 72. The back dielectric portion 71 is formed on the back surface 1bs’ of the device substrate 1’. The back conductive features 72 may include metallization layers (not shown) which are formed in the back dielectric portion 71, and backside vias 721 which extend out of the back dielectric portion 71, and which are respectively formed in and extends through the fin portions 1f so as to connect to the source/drain portions 212 of the transistors 21. In some embodiments, a metal silicide layer (not shown) may be formed between one of the backside vias 721 and a corresponding one of the source/drain portions 212 so as to reduce a contact resistance therebetween. In some embodiments, the back conductive features 72 further include through vias (not shown) which extend out of the back dielectric portion 71, and which are configured to be connected to the front conductive features in the front interconnect structure.

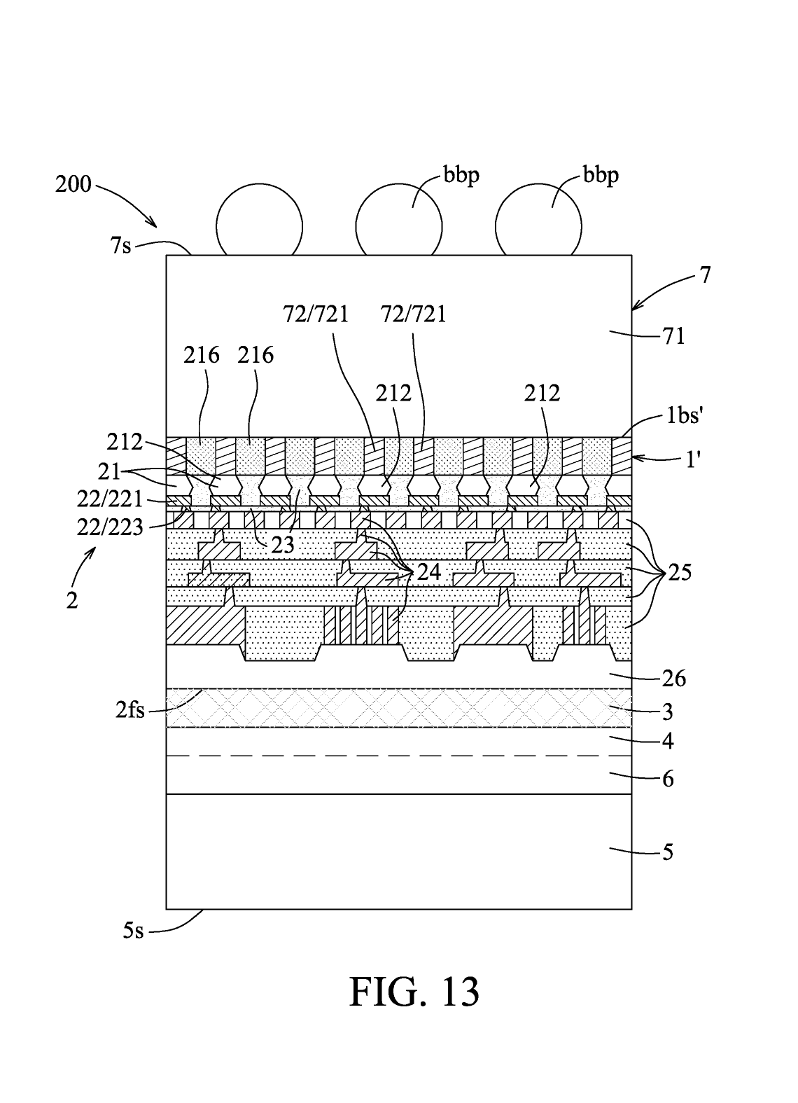

The semiconductor structure 200 may be further processed so as to be utilized in different applications. For instance, in some embodiments, as shown in FIG. 13, the semiconductor structure 200 may be further formed with bump contacts (bbp) which are disposed on an upper surface 7s of the back interconnect structure 7 opposite to the device substrate 1’.

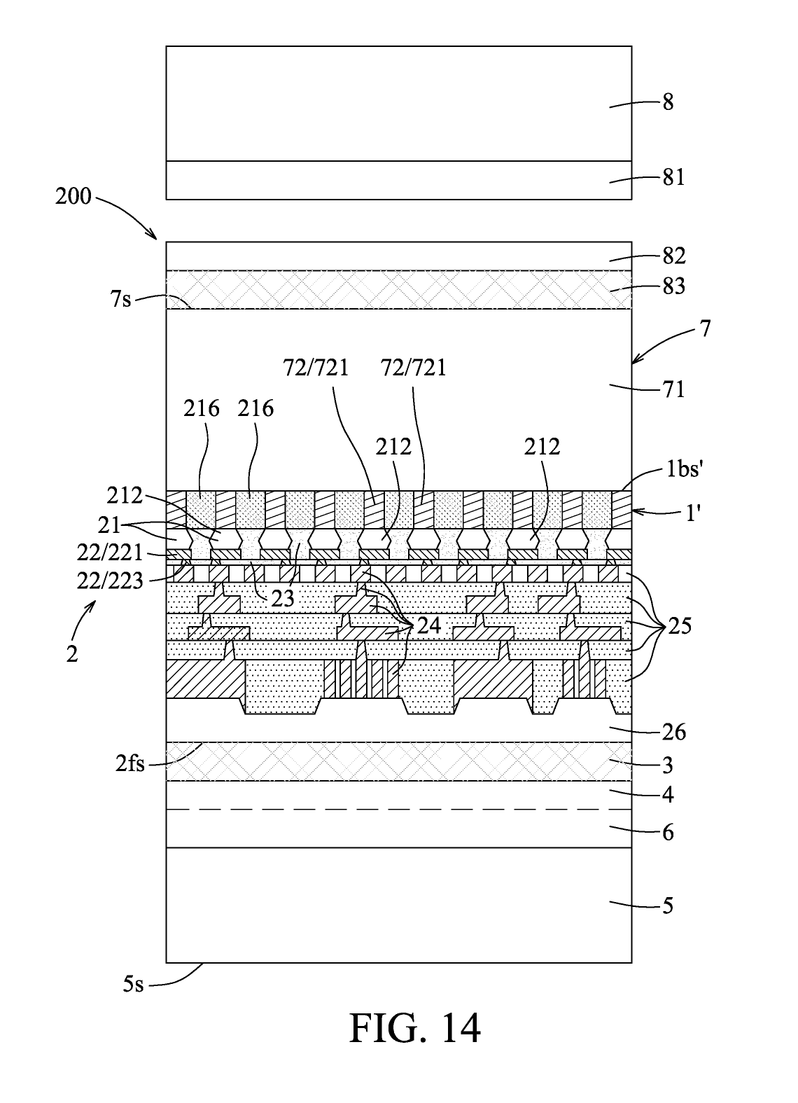

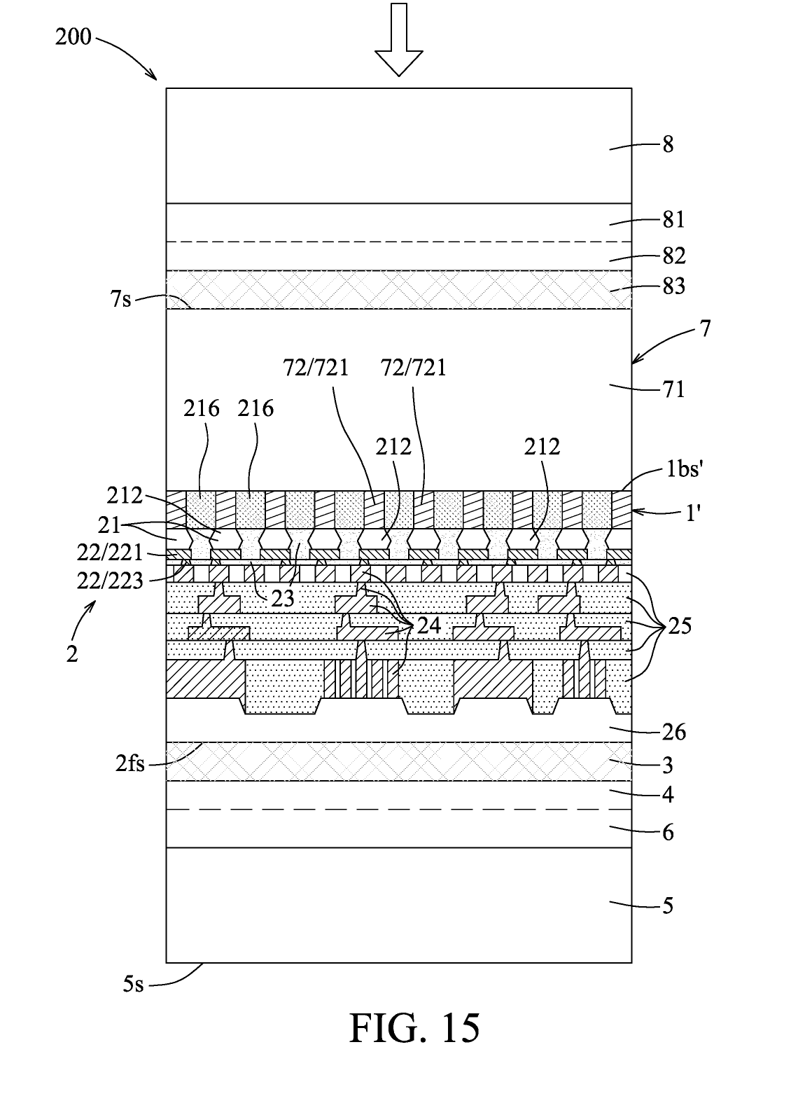

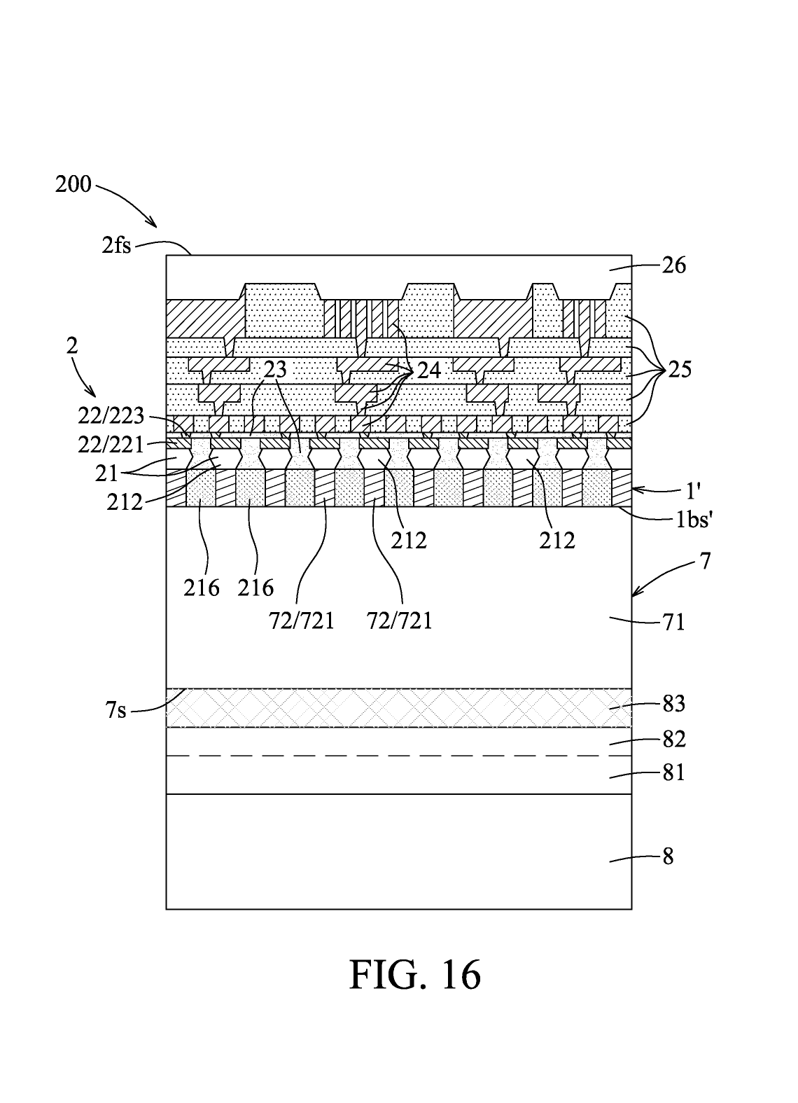

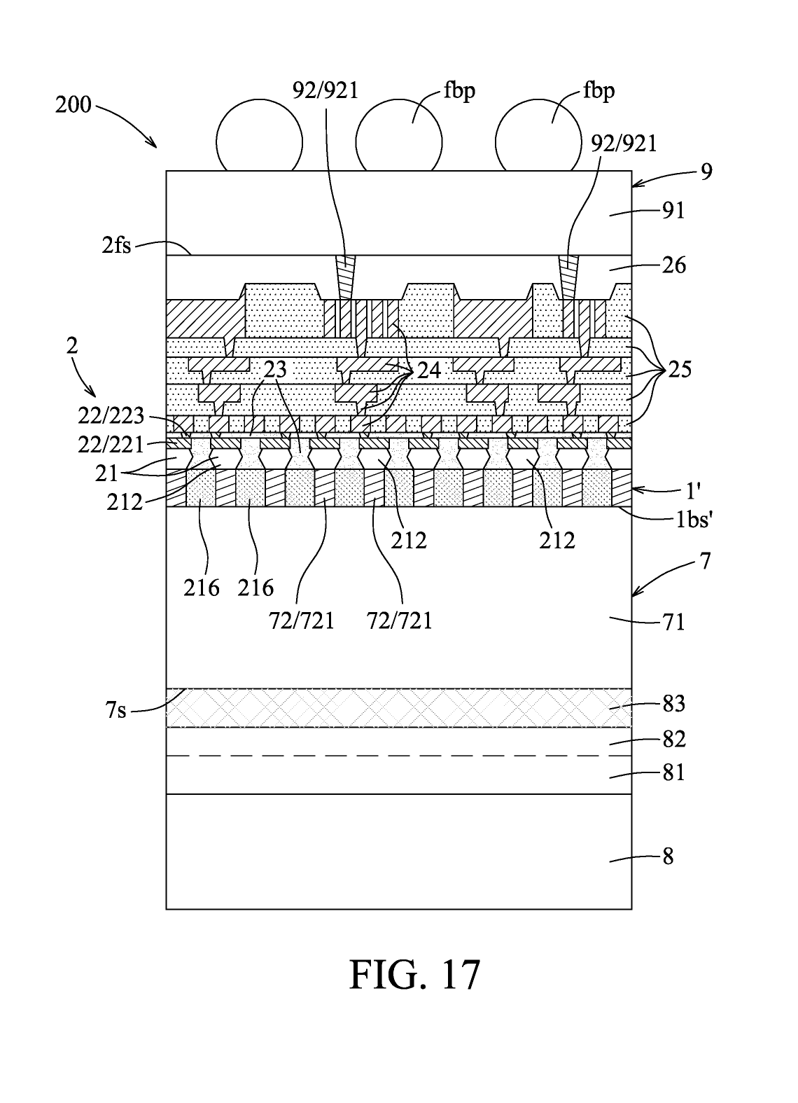

In some other embodiments, as shown in FIGS. 14 and 15, instead of formation of the bump contacts (bbp), a second bonding process is performed, such that the semiconductor structure 200 is bonded with a second carrier substrate 8 to through a second bonding unit. In some embodiments, the second carrier substrate 8 is a blanket substrate. The second carrier substrate 8 may include a semiconductor material (such as the examples of the semiconductor material for forming the device substrate 1), other materials with high thermal conductivity, or combinations thereof. In certain embodiments, the second carrier substrate 8 may be, for example, but not limited to, a blanket silicon substrate or a blanket diamond substrate. The second carrier substrate 8 may have a predetermined thickness according to practical needs. The second bonding unit may include a third bonding layer 81 formed on the second carrier substrate 8, and a fourth bonding layer 82 formed on the upper surface 7s of the back interconnect structure 7 opposite to the device substrate 1’. The bonding layers 81, 82 are made of the same material. In some embodiments, each of the bonding layers 81, 82 may be made of amorphous silicon oxide. In some other embodiments, each of the bonding layers 81, 82 may be made of aluminum oxide, titanium oxide, nickel oxide, zinc oxide, other materials with a high thermal conductivity, or combinations thereof. In some embodiments, the second bonding unit has a thickness ranging from about 100 nm to about 250 nm, but other range of values less than 100 nm (but not equal to 0 nm) are also within the contemplated scope of this disclosure. In some embodiments, an additional anti-deformation layer 83 may be further formed between the fourth bonding layer 82 and the back interconnect structure 7 so as to protect the back interconnect structure 7 and the device structure 2 disposed therebeneath from deformation which may be caused by a compressive stress used in the second bonding process. The configurations of the anti-deformation layer 83 are similar to those of the anti-deformation layer 3 as described above with reference to FIG. 4. That is, a Young’s modulus of the anti-deformation layer 83 is greater than a Young’s modulus of the back dielectric portion 71, and a compressive strength of the anti-deformation layer 83 is greater than a compressive strength of the back dielectric portion 71. In some embodiments, the Young’s modulus of the anti-deformation layer 83 may be even greater than the Young’s modulus of the back conductive features 72. In some embodiments, the anti-deformation layer 83 has a thickness ranging from about 5 nm to about 300 nm (e.g., about 5 nm to about 100 nm, about 10 nm to about 100 nm, or about 10 nm to about 300 nm). Since the materials suitable for forming the anti-deformation layer 83 are similar to those of the anti-deformation layer 3, the thermal conductivity, adhesion strength, thermal stability of the anti-deformation layer 83 are similar to those of the anti-deformation layer 3, and thus the details thereof are omitted for the sake of brevity. In some embodiments, the back dielectric portion 71 may have a first dielectric region in which the back conductive features 72 are formed, and a second dielectric region which is formed on the first dielectric region and which is formed with the upper surface 7s. In some embodiments, the back conductive features 72 are not formed in the second dielectric region, and the second dielectric region functions as a buffer layer which is capable to absorb the compressive stress used in the second bonding process. In some embodiments, the second dielectric region may have a thickness not greater than about 300 nm. Possible materials suitable for the second dielectric region are similar to the buffer material of the buffer layer 26, and thus the details thereof are omitted for the sake of brevity. In some embodiments, the second dielectric region is in contact with the anti-deformation layer 83. In some alternative embodiments not shown herein, the additional anti-deformation layer 83 may be formed between the third bonding layer 81 and the second carrier substrate 8. In such case, the second dielectric region may be in contact with the fourth bonding layer 82. Afterwards, as shown in FIG. 16, the semiconductor structure 200 shown in FIG. 15 is flipped to place the upper surface 5s of the first carrier substrate 5 facing upward, and then the first carrier substrate 5, the first and second bonding layers 4, 6 and the anti-deformation layer 3 are removed by a debonding process, a planarization process, an etching process, or other suitable removal techniques, so as to expose the buffer layer 26. Subsequently, as shown in FIG. 17, the semiconductor structure 200 is formed with a contact layer 9 which is disposed on the buffer layer 26, and bump contacts (fbp) which are disposed on the contact layer 9 opposite to the buffer layer 26. In some embodiments, the contact layer 9 includes a dielectric layer 91 and conductive features 92. The dielectric layer 91 is formed on the buffer layer 26. The conductive features 92 may include metallization layers (not shown) formed in the dielectric layer 91, and metallization contacts 921 (two of which are exemplarily shown in FIG. 17) which extend out of the dielectric layer 91 and which are configured to be connected to the front conductive features so as to permit the transistors 21 to be connected to the bump contacts (fbp) through the front conductive features and the conductive features 92.

In some embodiments, some steps in the method 100 may be modified, replaced, or eliminated without departure from the spirit and scope of the present disclosure. In some alternative embodiments, the semiconductor structure 200 may further include additional features, and/or some features present in the semiconductor structure 200 may be modified, replaced, or eliminated without departure from the spirit and scope of the present disclosure.

In summary, with the provision of the anti-deformation layer 3 which is disposed between the device structure 2 and the first carrier substrate 5, and which has a Young’s modulus and a compressive strength greater than those of the buffer layer 26, the deformation of the transistors 21 in the device structure 2 during the first bonding process can be significantly mitigated. Although the buffer layer 26 has a reduced thickness for improving thermal dissipation, the deformation of the transistors 21 can be minimized due to great protection provided by the anti-deformation layer 3. As such, the backside vias 721 can be well aligned with and connected to the source/drain portions 212 of the transistors 21, respectively, thereby improving the stability and reliability of the semiconductor structure 200. Furthermore, since the material suitable for the anti-deformation layer 3 has a thermal conductivity that is higher than the thermal conductivity of the buffer layer 26, the thermal dissipation of the semiconductor structure 200 may be improved when the anti-deformation layer 3 is present in the final product.

In accordance with some embodiments of the present disclosure, a method for manufacturing a semiconductor structure, includes: forming a device structure on a device substrate, the device structure having a front surface opposite to the device substrate, and including a buffer layer which is formed with the front surface; forming a first bonding layer on the front surface of the device structure; forming a second bonding layer on a first carrier substrate; performing a bonding process such that the device structure and the first carrier substrate are bonded to each other through the first bonding layer and the second bonding layer; and before the bonding process, forming an anti-deformation layer which is located between the first bonding layer and the device structure, or between the second bonding layer and the first carrier substrate. A Young’s modulus of the anti-deformation layer is greater than a Young’s modulus of the buffer layer, and a compressive strength of the anti-deformation layer is greater than a compressive strength of the buffer layer.

In accordance with some embodiments of the present disclosure, the anti-deformation layer is made of a material which includes silicon nitride, aluminum nitride, aluminum oxynitride, titanium nitride, tantalum nitride, aluminum oxide, titanium oxide, tantalum oxide, or combinations thereof.

In accordance with some embodiments of the present disclosure, the material of the anti-deformation layer is in an amorphous phase.

In accordance with some embodiments of the present disclosure, the first bonding layer is made of a first bonding material that is the same with a second bonding material of the second bonding layer.

In accordance with some embodiments of the present disclosure, each of the first bonding material and the second bonding material is made of silicon oxide.

In accordance with some embodiments of the present disclosure, the anti-deformation layer has a thickness ranging from 5 nm to 100 nm.

In accordance with some embodiments of the present disclosure, the first bonding layer and the second bonding layer have a total thickness ranging from 100 nm to 250 nm.

In accordance with some embodiments of the present disclosure, the buffer layer is made of a buffer material which includes silicon oxide, nitrogen-doped silicon oxide, carbon-doped silicon oxide, silicon oxycarbon nitride, or combinations thereof.

In accordance with some embodiments of the present disclosure, the buffer material is in an amorphous phase.

In accordance with some embodiments of the present disclosure, a method for manufacturing a semiconductor structure, includes: forming a device structure on a device substrate, the device structure having a front surface opposite to the device substrate, and including a buffer layer which is formed with the front surface; forming a first anti-deformation layer on the front surface of the device structure, a Young’s modulus of the first anti-deformation layer being greater than a Young’s modulus of the buffer layer, a compressive strength of the first anti-deformation layer being greater than a compressive strength of the buffer layer; forming a first bonding layer on the anti-deformation layer opposite to the buffer layer; forming a second bonding layer on a first carrier substrate; and performing a first bonding process to bond the first carrier substrate to the device structure through the first bonding layer and the second bonding layer, the device structure being formed with the anti-deformation layer.

In accordance with some embodiments of the present disclosure, the front surface is a planar surface.

In accordance with some embodiments of the present disclosure, the first anti-deformation layer is made of a material which includes silicon nitride, aluminum nitride, aluminum oxynitride, titanium nitride, tantalum nitride, aluminum oxide, titanium oxide, tantalum oxide, or combinations thereof.

In accordance with some embodiments of the present disclosure, the material of the first anti-deformation layer is in an amorphous phase.

In accordance with some embodiments of the present disclosure, the device structure further includes a device formed on the device substrate, and a front interconnect structure formed between the device and the buffer layer. The device includes a channel, two source/drain portions which are respectively disposed at two opposite sides of the channel, and a gate structure which is disposed on the channel. The front interconnect structure includes a front dielectric portion which is formed to cover the device, and front conductive features which are formed in the front dielectric portion and which are connected to the device.

In accordance with some embodiments of the present disclosure, the method further includes: after the first bonding process, thinning down the device substrate from a back surface of the device substrate opposite to the front surface; and after the device substrate is thinned down, forming a back interconnect structure on the back surface of the device substrate. The back interconnect structure including a back dielectric portion and back conductive features which are formed in the back dielectric portion and which extend through the device substrate to be connected to the device.

In accordance with some embodiments of the present disclosure, the method further includes: performing a second bonding process to bond a second carrier substrate to the back interconnect structure through a bonding unit so that the second carrier substrate is disposed on the back interconnect structure opposite to the first carrier substrate; removing the first carrier substrate and the second bonding layer to expose the first bonding layer; and removing the first bonding layer and the anti-deformation layer to expose the buffer layer.

In accordance with some embodiments of the present disclosure, the method further includes forming a second anti-deformation layer. The second anti-deformation layer is located between the bonding unit and the back interconnect structure, or between the bonding unit and the second carrier substrate. A Young’s modulus of the second anti-deformation layer is greater than a Young’s modulus of the back dielectric portion, and a compressive strength of the second anti-deformation layer is greater than a compressive strength of the back dielectric portion.

In accordance with some embodiments of the present disclosure, a semiconductor structure, includes: a device substrate; a device structure disposed on the device substrate, the device structure having a front surface opposite to the device substrate, and including a buffer layer which is formed with the front surface; a carrier substrate; a bonding unit disposed to bond the carrier substrate to the front surface of the device structure, the bonding unit including a first bonding layer disposed on the front surface of the device structure and a second bonding layer disposed on the carrier substrate; and an anti-deformation layer which is disposed between the first bonding layer and the device structure, or between the second bonding layer and the carrier substrate. A Young’s modulus of the anti-deformation layer is greater than a Young’s modulus of the buffer layer, and a compressive strength of the anti-deformation layer is greater than a compressive strength of the buffer layer.

In accordance with some embodiments of the present disclosure, the anti-deformation layer is made of a material which includes silicon nitride, aluminum nitride, aluminum oxynitride, titanium nitride, tantalum nitride, aluminum oxide, titanium oxide, tantalum oxide, or combinations thereof. The buffer layer is made of a buffer material which includes silicon oxide, nitrogen-doped silicon oxide, carbon-doped silicon oxide, silicon oxycarbon nitride, or combinations thereof.

In accordance with some embodiments of the present disclosure, the buffer material and the material of the first anti-deformation layer are in an amorphous phase.

In accordance with some embodiments of the present disclosure, a method for manufacturing a semiconductor structure, includes: forming a device structure on a device substrate, the device structure having a front surface opposite to the device substrate, and including a buffer layer which is formed with the front surface; forming a first bonding layer on the front surface of the device structure; forming an anti-deformation layer on a carrier substrate, a Young’s modulus of the anti-deformation layer being greater than a Young’s modulus of the buffer layer, a compressive strength of the anti-deformation layer being greater than a compressive strength of the buffer layer; forming a second bonding layer on the anti-deformation layer opposite to the carrier substrate; and performing a bonding process to bond the device structure to the carrier substrate through the first bonding layer and the second bonding layer, the carrier substrate being formed with the anti-deformation layer.

In accordance with some embodiments of the present disclosure, the anti-deformation layer is made of a material which includes silicon nitride, aluminum nitride, aluminum oxynitride, titanium nitride, tantalum nitride, aluminum oxide, titanium oxide, tantalum oxide, or combinations thereof. The buffer layer is made of a buffer material which includes silicon oxide, nitrogen-doped silicon oxide, carbon-doped silicon oxide, silicon oxycarbon nitride, or combinations thereof.

In accordance with some embodiments of the present disclosure, the buffer material and the material of the first anti-deformation layer are in an amorphous phase.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing a semiconductor structure, comprising:
forming a device structure on a device substrate, the device structure having a front surface opposite to the device substrate, and including a buffer layer which is formed with the front surface;
forming a first bonding layer on the front surface of the device structure;
forming a second bonding layer on a first carrier substrate;
performing a bonding process such that the device structure and the first carrier substrate are bonded to each other through the first bonding layer and the second bonding layer; and
before the bonding process, forming an anti-deformation layer, the anti-deformation layer being located between the first bonding layer and the device structure, or between the second bonding layer and the first carrier substrate, a Young’s modulus of the anti-deformation layer being greater than a Young’s modulus of the buffer layer, a compressive strength of the anti-deformation layer being greater than a compressive strength of the buffer layer.

2. The method as claimed in claim 1, wherein the anti-deformation layer is made of a material which includes silicon nitride, aluminum nitride, aluminum oxynitride, titanium nitride, tantalum nitride, aluminum oxide, titanium oxide, tantalum oxide, or combinations thereof.

3. The method as claimed in claim 2, wherein the material of the anti-deformation layer is in an amorphous phase.

4. The method as claimed in claim 3, wherein the first bonding layer is made of a first bonding material that is the same with a second bonding material of the second bonding layer.

5. The method as claimed in claim 4, wherein each of the first bonding material and the second bonding material is made of silicon oxide.

6. The method as claimed in claim 1, wherein the anti-deformation layer has a thickness ranging from 5 nm to 100 nm.

7. The method as claimed in claim 1, wherein the first bonding layer and the second bonding layer have a total thickness ranging from 100 nm to 250 nm.

8. The method as claimed in claim 1, wherein the buffer layer is made of a buffer material which includes silicon oxide, nitrogen-doped silicon oxide, carbon-doped silicon oxide, silicon oxycarbon nitride, or combinations thereof.

9. The method as claimed in claim 8, wherein the buffer material is in an amorphous phase.

10. A method for manufacturing a semiconductor structure, comprising:
forming a device structure on a device substrate, the device structure having a front surface opposite to the device substrate, and including a buffer layer which is formed with the front surface;
forming a first anti-deformation layer on the front surface of the device structure, a Young’s modulus of the first anti-deformation layer being greater than a Young’s modulus of the buffer layer, a compressive strength of the first anti-deformation layer being greater than a compressive strength of the buffer layer;
forming a first bonding layer on the anti-deformation layer opposite to the buffer layer;
forming a second bonding layer on a first carrier substrate; and
performing a first bonding process to bond the first carrier substrate to the device structure through the first bonding layer and the second bonding layer, the device structure being formed with the anti-deformation layer.

11. The method as claimed in claim 10, wherein the front surface is a planar surface.

12. The method as claimed in claim 10, wherein the first anti-deformation layer is made of a material which includes silicon nitride, aluminum nitride, aluminum oxynitride, titanium nitride, tantalum nitride, aluminum oxide, titanium oxide, tantalum oxide, or combinations thereof.

13. The method as claimed in claim 12, wherein the material of the first anti-deformation layer is in an amorphous phase.

14. The method as claimed in claim 10, wherein the device structure further includes
a device formed on the device substrate, the device including a channel, two source/drain portions which are respectively disposed at two opposite sides of the channel, and a gate structure which is disposed on the channel, and
a front interconnect structure formed between the device and the buffer layer, the front interconnect structure including a front dielectric portion which is formed to cover the device, and front conductive features which are formed in the front dielectric portion and which are connected to the device.

15. The method as claimed in claim 14, further comprising:
after the first bonding process, thinning down the device substrate from a back surface of the device substrate opposite to the front surface; and
after the device substrate is thinned down, forming a back interconnect structure on the back surface of the device substrate, the back interconnect structure including a back dielectric portion and back conductive features which are formed in the back dielectric portion and which extend through the device substrate to be connected to the device.

16. The method as claimed in claim 15, further comprising:
performing a second bonding process to bond a second carrier substrate to the back interconnect structure through a bonding unit so that the second carrier substrate is disposed on the back interconnect structure opposite to the first carrier substrate;
removing the first carrier substrate and the second bonding layer to expose the first bonding layer; and
removing the first bonding layer and the anti-deformation layer to expose the buffer layer.

17. The method as claimed in claim 16, further comprising forming a second anti-deformation layer, the second anti-deformation layer being located between the bonding unit and the back interconnect structure, or between the bonding unit and the second carrier substrate, a Young’s modulus of the second anti-deformation layer being greater than a Young’s modulus of the back dielectric portion, a compressive strength of the second anti-deformation layer being greater than a compressive strength of the back dielectric portion.

18. A semiconductor structure, comprising:
a device structure having a surface, and including a buffer layer which is formed with the surface;
a substrate;
a bonding unit disposed to bond the substrate to the surface of the device structure, the bonding unit including a first bonding layer disposed on the surface of the device structure and a second bonding layer disposed on the substrate; and
an anti-deformation layer which is disposed between the first bonding layer and the device structure, or between the second bonding layer and the substrate, a Young’s modulus of the anti-deformation layer being greater than a Young’s modulus of the buffer layer, a compressive strength of the anti-deformation layer being greater than a compressive strength of the buffer layer.

19. The semiconductor structure as claimed in claim 18, wherein
the anti-deformation layer is made of a material which includes silicon nitride, aluminum nitride, aluminum oxynitride, titanium nitride, tantalum nitride, aluminum oxide, titanium oxide, tantalum oxide, or combinations thereof, and
the buffer layer is made of a buffer material which includes silicon oxide, nitrogen-doped silicon oxide, carbon-doped silicon oxide, silicon oxycarbon nitride, or combinations thereof.

20. The semiconductor structure as claimed in claim 19, wherein the buffer material and the material of the first anti-deformation layer are in an amorphous phase.
